(19) United States
(12) Patent Application Publication
(10) Pub. No.: US 2018/0081450 A1
(43) Pub. Date: Mar. 22, 2018

(54) CUSTOMIZE INPUT DEVICE AND CUSTOMIZE BUTTON INPUT METHOD

(71) Applicant: SHENZHEN YUANYO TECHNOLOGY CO., LTD., Shenzhen (CN)

(72) Inventors: Chun-Hsien YEH, Shenzhen (CN); Teng-Chi CHANG, Shenzhen (CN)

(21) Appl. No.: 15/680,192

(22) Filed: Aug. 17, 2017

(30) Foreign Application Priority Data
Sep. 20, 2016 (CN) 201610834799.3

(51) Int. Cl. G06F 3/02; H03K 17/96

(52) U.S. Cl. CPC G06F 3/02; G06F 3/03543; H03K 17/9622

(57) ABSTRACT

The present disclosure provides a customize input device and a customize button input method. The customize input device includes a button, a sensing module, a storage module, and a processor. The sensing module is disposed under the button for measuring a displacement of the button. The storage module is used for storing a triggering condition of the button. The processor is connected to the sensing module to compare the displacement with the triggering condition. When the displacement coincides with the triggering condition, the processor sends a triggering signal.

### CROSS-REFERENCE TO RELATED APPLICATION

This application claims priority to China Application Serial Number 201610834799.3, filed Sep. 20, 2016, which is herein incorporated by reference.

### BACKGROUND OF THE INVENTION

### Field of Invention

The present invention relates to an input device and an input method. More particularly, the present invention relates to a customize input device and a customize button input method.

### Description of Related Art

To satisfy the requirements of operation convenience, various peripheral devices (e.g., a keyboard, mouse, and touch panel) are used with computers. Using such devices, the user can control the computer or perform data entry by pressing, sliding on, or moving the devices.

Among the various peripheral devices, the keyboard and mouse are the most popular and easiest to operate. However, as the computer industry has developed, the requirements of users have increased accordingly. Therefore, improving the operation experience of users has become an important issue.

The description of the related art is merely used to understand the overall background of the disclosure, and should not be regarded as admitting or implying that the information is well-known by those skilled in the art.

### SUMMARY OF THE INVENTION

The invention provides a customize input device and a customize button input method. To achieve a customize setting button, the triggering condition of each button coincides with a particular user's habit. Thus, the button can be triggered immediately and inadvertent triggering can be prevented.

An embodiment of the disclosure provides a customize input device including a button, a sensing module, a storage module, and a processor. The sensing module is disposed under the button to measure a displacement of the button. The storage module is used to store a triggering condition of the button. The processor is connected to the sensing module to check the displacement matching the triggering condition or not. Once the displacement coincides with the triggering condition, the processor sends a triggering signal.

In some embodiments of the present disclosure, the button is a key of a keyboard or a button of a mouse.

In some embodiments of the present disclosure, the button, the sensing module, and the triggering condition are plural, and each of the triggering conditions corresponds to one of the buttons, or corresponds to a group of the buttons.

In some embodiments of the present disclosure, the sensing module is a capacitive sensing module, a magnetic sensing module, an infrared sensing module, a resister sensing module, or an ultrasonic sensing module. (Please refer the claim section)

In some embodiments of the present disclosure, the sensing module is a piezoelectric sensing module.

Another embodiment of the disclosure provides a customize button input method. The method includes setting a triggering condition of a button. Next, the triggering condition is stored in a storage module. When the button is pressed, a displacement of the button is measured. Subsequently, the displacement is compared with the triggering condition, and a triggering signal is sent when the displacement coincides with the triggering condition.

In some embodiments of the present disclosure, measuring the displacement of the button is applied through a contact measurement.

In some embodiments of the present disclosure, measuring the displacement of the button is applied through a contactless measurement.

In some embodiments of the present disclosure, the method further includes setting a release condition of the button, and storing the release condition in a storage module. Next, the displacement is compared with the release condition. When the displacement coincides with the release condition, a release signal is sent.

In some embodiments of the present disclosure, the triggering condition is a threshold or a slope.

In the customize input device of the present disclosure, the triggering condition of the button is predetermined, such that the triggering condition of each button corresponds to a particular user's habit to thereby achieve a customize setting button. Thus, the button may be triggered immediately and inadvertent triggering may be prevented.

### BRIEF DESCRIPTION OF THE DRAWINGS

The invention can be more fully understood by reading the following detailed description of the embodiment, with reference made to the accompanying drawings as follows:

FIGS. 1 and 2 are block diagrams of customize input devices according to some embodiments of the disclosure.

FIGS. 3A to 3G are sectional views of customize input devices according to some embodiments of the disclosure.

FIGS. 4A and 4B are schematic views of a triggering/release condition of a customize input device according to some embodiments of the disclosure.

FIG. 5 is a flow chart of a customize button input method according to an embodiment of the disclosure.

### DETAILED DESCRIPTION

Reference will now be made in detail to the present embodiments of the invention, examples of which are illustrated in the accompanying drawings. Those skilled in the art should also realize that such equivalent constructions do not depart from the spirit and scope of the present disclosure, and that they may make various changes, substitutions, and alterations herein without departing from the spirit and scope of the present disclosure.

The triggering conditions of each button may be set in advance according to the customize input device of the present disclosure, such as the strength for triggering each button. Further, according to the operation habit of different users, the customize settings may be achieved. Further, the individual setting can be achieved according to the various habits of different users.

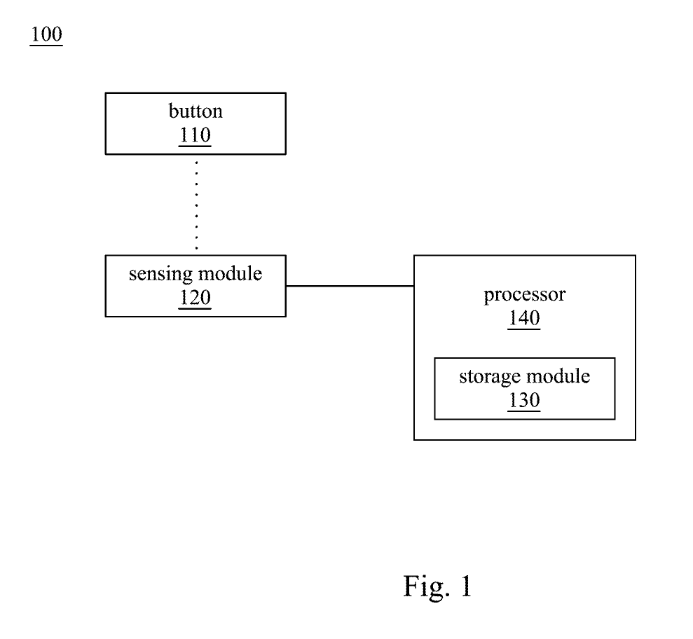

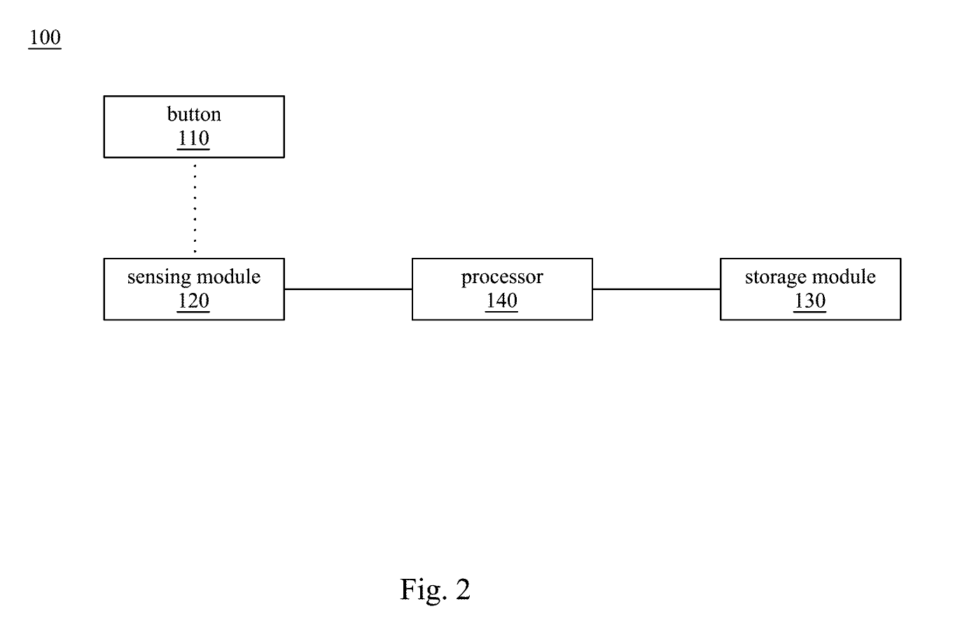

FIGS. 1 and 2 are block diagrams of customize input devices according to some embodiments of the disclosure. A customize input device 100 includes a button 110, a sensing module 120, a storage module 130, and a processor 140. The sensing module 120 is disposed under the button 110 for measuring a displacement when the button 110 is pressed. The displacement of the button 110 measured by the sensing module 120 is transmitted to the processor 140, in which the processor 140 verifies if the displacement coincides with a predetermined triggering condition of the button 110 in the storage module 130. Once the displacement coincides with the predetermined triggering condition, the processor 140 sends a triggering signal to a computer, such that the computer executes an operation corresponding to the button 110.

For example, the button 110 may be included in a mechanical keyboard or a membrane keyboard. The button 110 may also be a left/right button or a wheel button of a mouse. The sensing module 120 is disposed under the button 110. That is, a vertical projection of the button 110 and a vertical projection of the sensing module 120, such as the vertical projections on a circuit board or a bottom case, are at least partially overlapped. When the button 110 is pressed, the sensing module 120 measures the displacement of the button 110 through a contact measurement or a contactless measurement. Various embodiments of the sensing module 120 will be described hereinafter. The described displacement indicates the distance variation between the button 110 and the circuit board (or the bottom case) when the button 110 is pressed. Since the customize input device may be disposed at different positions, the displacement need not to coincide with the displacement in the gravity direction.

In some embodiments, the processor 140 may be integrated in a control chip of the corresponding customize input device 100. For example, if the button 110 is a keyboard button, the processor 140 is integrated in the control chip of the keyboard. If the button 110 is a mouse button, the processor 140 is integrated in the control chip of the mouse. In some other embodiments, the processor 140 is integrated in a computer connected to the input device, such that the above operations are performed through the computer.

The storage module 130, for example, may be flash memory, random access memory (RAM), one time programmable memory (OPT Memory), or electrically-erasable programmable read-only memory (EEPROM). The storage module 130 may be embedded in the processor 140, as shown in FIG. 1. Alternatively, the storage module 130 may be disposed external to the processor 140, as shown in FIG. 2.

In the present disclosure, the triggering condition of each button is set in advance according to personal requirements. For example, if a user would like to trigger some certain buttons quickly, such as the combination buttons in games, these buttons may be set with a slighter triggering strength to reduce the response time of the buttons. Alternatively, since there are some commonly used buttons at inconvenient positions on the keyboard, such as the ESC button, these buttons may be set with a slighter triggering strength, such that it is easy for the ring finger or the small finger to trigger these buttons. On the other hand, to prevent inadvertent triggering of some buttons with specific functions, such as the ESC button or ENTER button, these buttons may be set with a stronger triggering strength to avoid such inadvertent triggering. The above descriptions are merely used to explain the present disclosure, and should not be used to limit the present disclosure. The user may set the triggering condition of each button according to individual preferences.

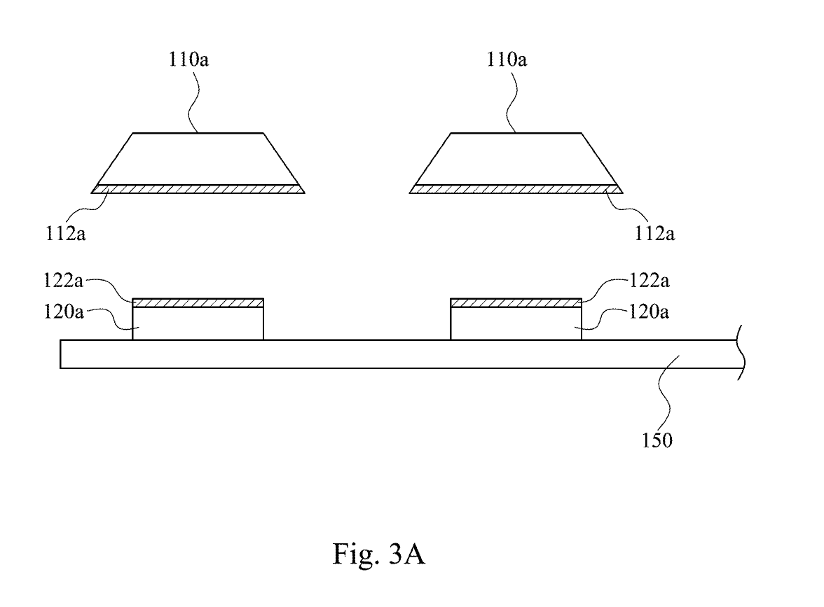

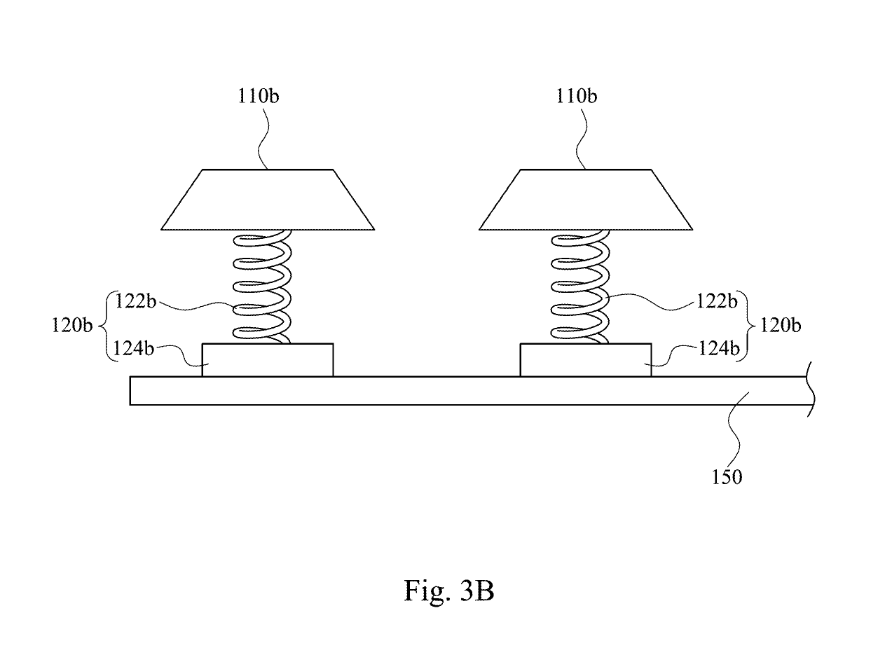

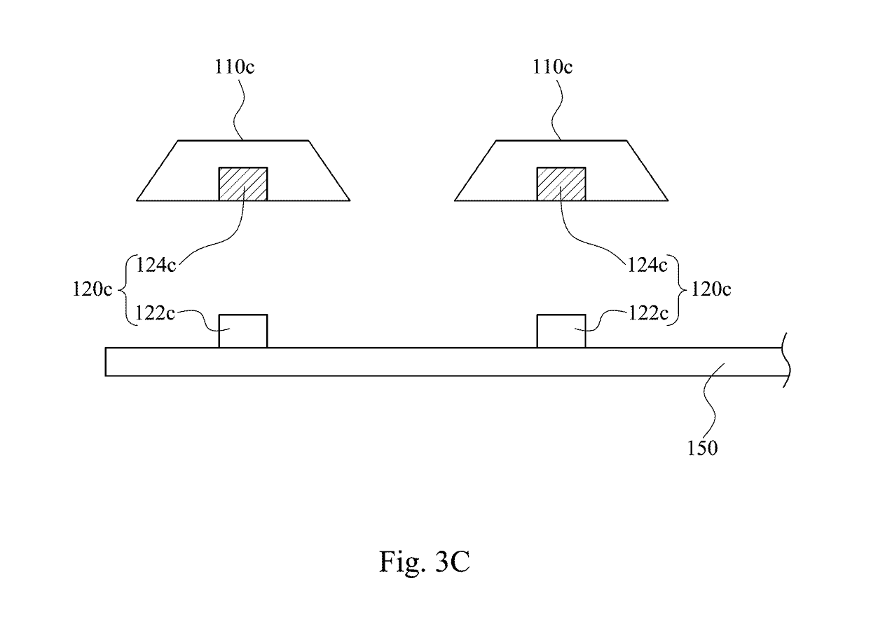

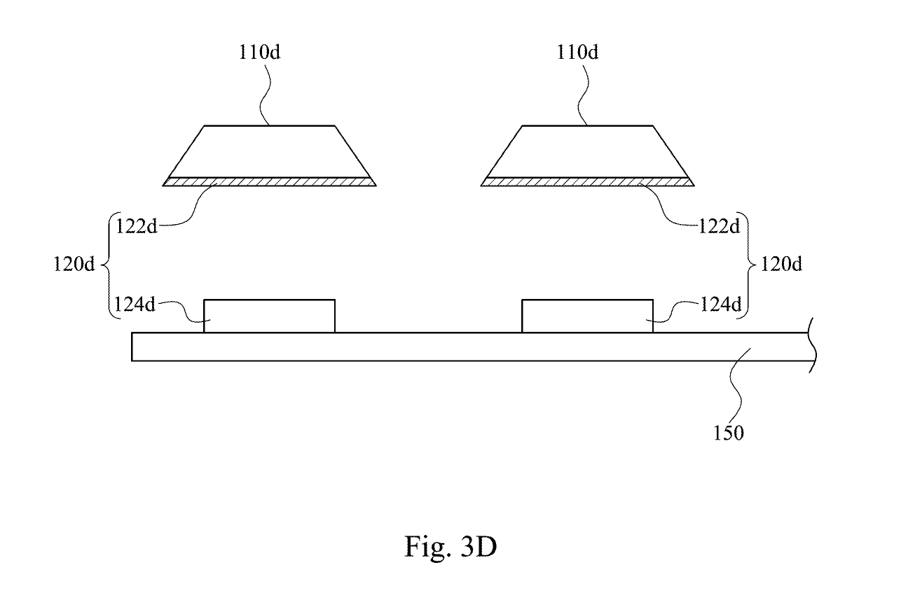

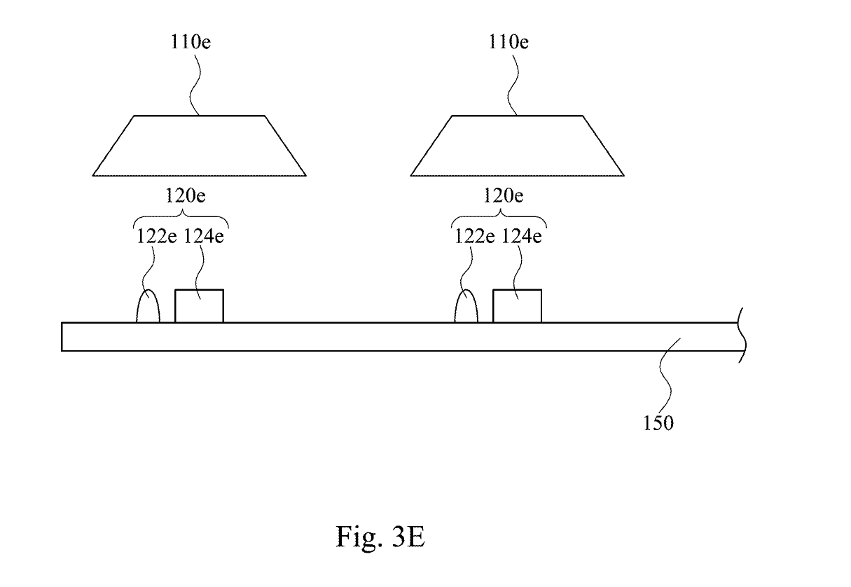

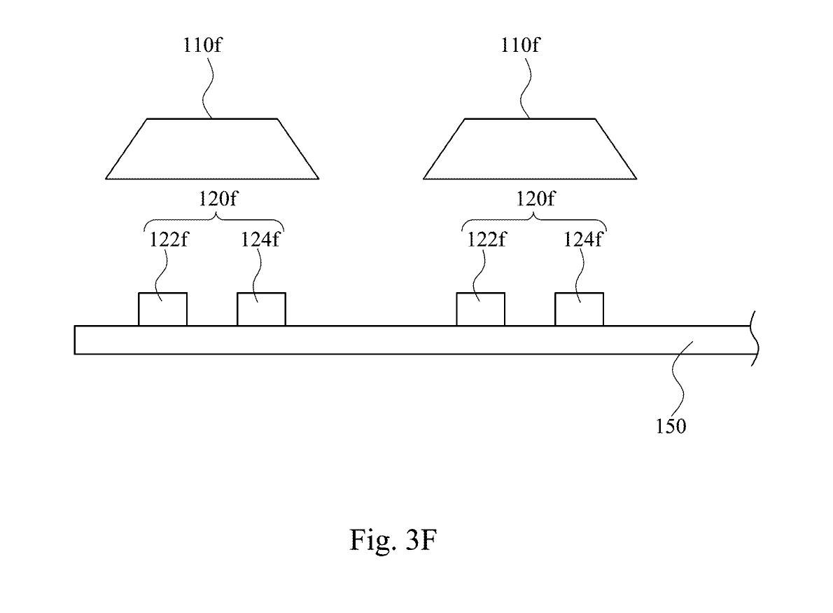

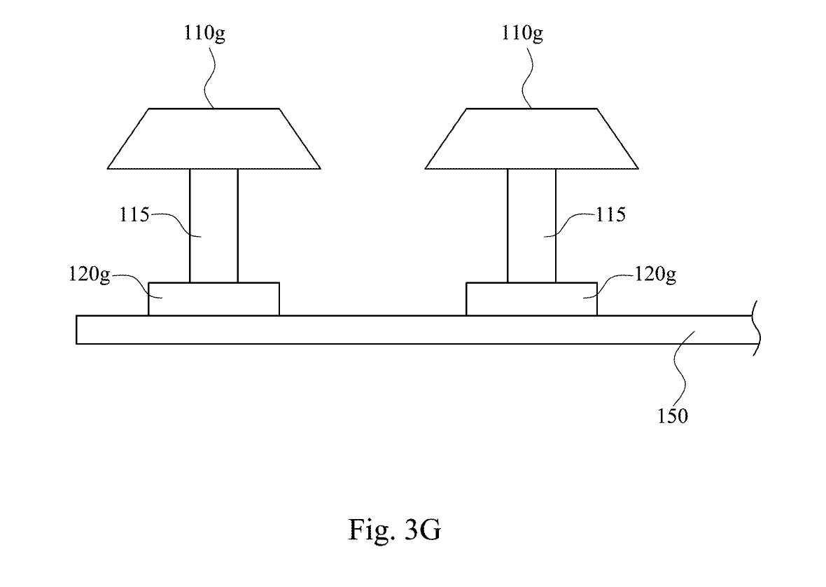

FIGS. 3A to 3G are sectional views of customize input devices according to some embodiments of the disclosure. The differences in the embodiments of FIGS. 3A to 3G relate to their sensing modules. Referring to FIG. 3A, two sensing modules 120a are disposed under two buttons 110a, respectively. The sensing modules 120a are disposed on a circuit board 150. The circuit board 150 has a storage module and a processor (not shown). The circuit board 150 electrically connects the storage module and the processor to the sensing modules 120a. The sensing modules 120a may be capacitive sensing modules. Each of the sensing modules 120a includes a conductive layer 122a. An electric field is applied to the conductive layer 122a. The material of the buttons 110a may include a conductor, such as metal or conductive rubber. In this embodiment, other conductive layers 112a are disposed on the surfaces of the buttons 110a facing the sensing modules 120a, respectively. When the buttons 110a approach the sensing modules 120a, due to the decreased distances between the conductive layers 112a and 122a, the capacitances between the buttons 110a and sensing modules 120a increase accordingly. The capacitance variations are detected by the sensing modules 120a, and the sensing modules 120a send the detected capacitances to the processor. The capacitances depend on the areas of the conductive layers 112a and 122a, the distances between the conductive layers 112a and 122a, and the dielectric constant of the medium between the conductive layers 112a and 122a. Since the areas of the conductive layers 112a and 122a, and the dielectric constant are constant, the capacitance variations mainly depend on the distance variations of the buttons 110a and the sensing modules 120a. Further, since the sensing modules 120a are fixed in position, the capacitance variations depend on the displacements of the buttons 110a. The sensing modules 120a send the detected capacitances to the processor, and the processor determines if the buttons 110a are pressed by checking the predetermined triggering condition.

Referring to FIG. 3B, this embodiment differs from the embodiment of FIG. 3A, in that sensing modules 120b of this embodiment are a different type of capacitive sensing module. The two sensing modules 120b each includes a spring 122b and a sensing circuit 124b. The springs 122b are disposed under the buttons 110b, and the sensing circuits 124b are disposed on the circuit board 150. Alternatively, in some other embodiments, if the buttons 110b include mechanical axles, the springs 122b may also be disposed on the mechanical axles. The springs 122b may be metal. One end of each of the springs 122b is in contact with the sensing circuit 124b. When the buttons 110b are pressed, the springs 122b below are pressed and deformed accordingly. As the springs 122b are pressed, the distances between the metal rings of the springs 122b decrease, such that the capacitances detected by the sensing circuit 124b increase. Therefore, the capacitance variations depend on the displacements of the buttons 110b.

Referring to FIG. 3C, this embodiment differs from the embodiment of FIG. 3A, in that the sensing modules 120c in the present embodiment are magnetic sensing modules. Each of the sensing modules 120c includes a Hall sensor 122c and a magnet 124c. The Hall sensors 122c are disposed on the circuit board 150, and the magnets 124c are disposed on the buttons 110c. The Hall sensors 122c may be applied to detect the variation of magnetic lines. For example, when the buttons 110c are pressed, the buttons 110c may gradually approach the circuit board 150. Thus, the densities of the magnetic lines detected by the Hall sensors 122c increase accordingly, such that output voltages of the Hall sensors 122c also increase accordingly. That is, the output voltages of the Hall sensors 122c depend on the displacements of the buttons 110b.

Referring to FIG. 3D, this embodiment differs from the embodiment of FIG. 3A, in that the sensing modules 120d in the present embodiment are another type of magnetic sensing modules. Each of the sensing modules 120d includes a conductive layer 122d disposed under the corresponding button 110d, and a sensing layer 124d disposed on the circuit board 150. Each of the sensing layers 124d includes a magnetic material and a sensing circuit, in which the magnetic material is used for generating magnetic lines, and the sensing circuit is used for sensing the variation of the magnetic lines. When the buttons 110d are pressed, the buttons 110d approach the circuit board 150. Accordingly, the conductive layers 122d approach the sensing layers 124d, such that the distributions of magnetic lines of the sensing layers 124d are destroyed. As a result, the sensing circuit detects the variations of magnetic fields and further changes the output voltages thereof.

Referring to FIG. 3E, the difference between the embodiments of FIGS. 3E and 3A resides in that the sensing modules 120e in the present embodiment are infrared sensing modules. Each of the sensing modules 120e includes an infrared emitter 122e and an infrared receiver 124e, both disposed on the circuit board 150. The infrared emitters 122e may be infrared diodes with a constant emitting frequency. The infrared rays generated by the infrared emitters 122e may transmit directly forward until they are reflected by the buttons 110e, and the reflected infrared rays are received by the infrared receivers 124e. The distances between the buttons 110e and the sensing modules 120e may be determined by calculating the time delay of the infrared rays between emission and reception. Once the distances between the buttons 110e and the sensing modules 120e change, the displacements of the buttons 110e are determined accordingly.

Referring to FIG. 3F, the difference between the embodiments of FIGS. 3F and 3A resides in that the sensing modules 120f in the present embodiment are ultrasonic sensing modules. Each of the sensing modules 120f includes an ultrasonic emitter 122f and an ultrasonic receiver 124f, both disposed on the circuit board 150. The ultrasonic emitters 122f generate ultrasounds with a constant emitting frequency. The ultrasounds generated by the ultrasonic emitters 122f may transmit directly forward until they are reflected by the buttons 110f, and the reflected ultrasounds are received by the ultrasonic receivers 124f. The distances between the buttons 110f and the sensing modules 120f may be determined by calculating the time delay of the ultrasounds between emission and reception. Once the distances between the buttons 110f and the sensing modules 120f change, the displacements of the buttons 110f are determined accordingly.

Referring to FIG. 3G, the difference between the embodiments of FIGS. 3G and 3A resides in that the sensing modules 120g in the present embodiment are voltage sensing modules. Each of the sensing modules 120g includes a piezoelectric material disposed under one of the buttons 110g. Each of the buttons 110g includes a pressing part 115. When the buttons 110g are not pressed, the pressing parts 115 may be flatly attached on the piezoelectric materials or may be disposed slightly above the piezoelectric materials. Thus, the voltages of the buttons 110g maintain a certain value or a value close to 0 when the buttons 110g are not pressed. When the buttons 110g are pressed, the pressing parts 115 on the buttons 110g will squeeze the piezoelectric materials, such that the voltages of the opposite end sides of the piezoelectric materials change. If the displacements of the buttons 110g increase, the strengths received by the piezoelectric materials increase accordingly. Therefore, the voltages generated by the piezoelectric materials increase accordingly. The piezoelectric materials may be a single crystal, such as quartz, LiNbO₃, or LiTaO₃. The piezoelectric materials may also be a thin film, such as AlN or ZnO. The piezoelectric materials may also be ceramic, such as BaTiO₃ (BT) or Pb(ZrTi)O₃ (PZT), or a polymer, such as poly (vinylidene fluoride) (PVDF). The displacements of the buttons 110g may be determined through measuring the voltage variations (or resistance variations) of the piezoelectric materials.

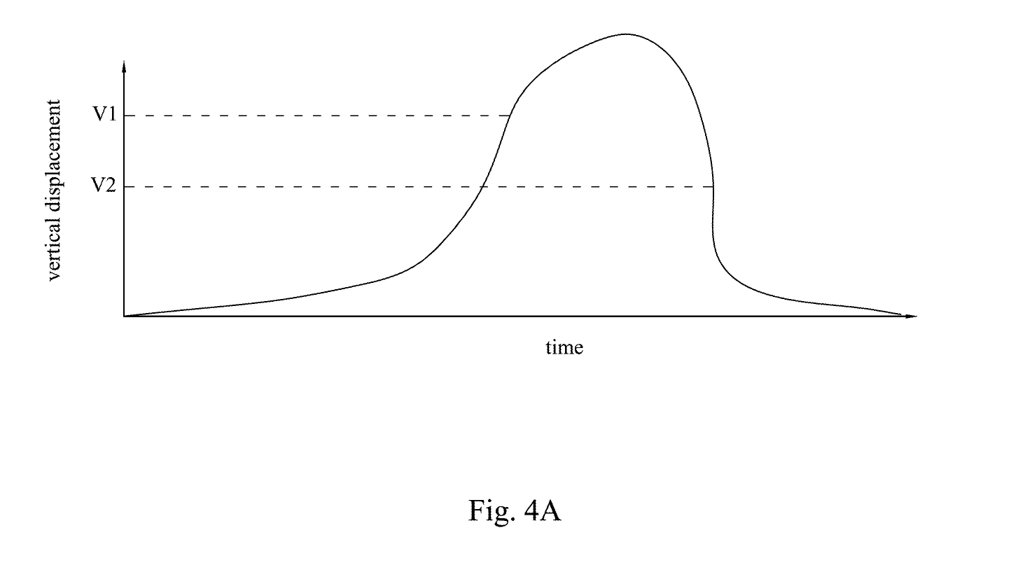

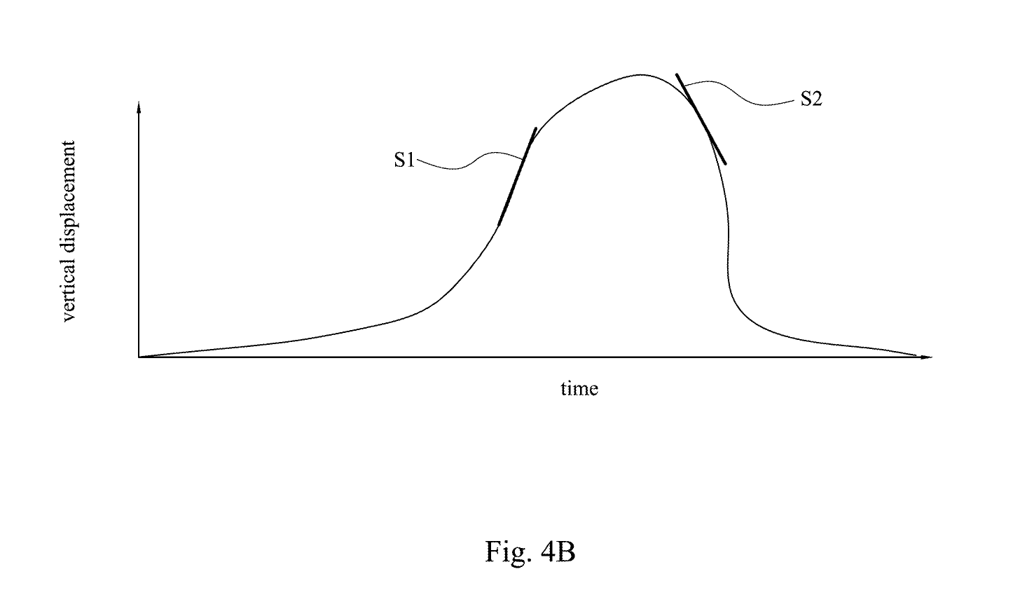

FIGS. 4A and 4B are schematic views of a triggering/release condition of a customize input device according to some embodiments of the disclosure. The lateral axis corresponds to time (ms), and the vertical axis corresponds to displacement. As described above, a sensing module can measure a displacement of a button through a contact measurement or a contactless measurement. The displacement may be expressed in distance, capacitance variation, voltage variation, and resistance variation. The displacement detected by the sensing module is transmitted to the processor and compared with the predetermined triggering/release condition to verify if the button is triggered/released.

Referring to FIG. 4A, the triggering condition of the button may be set as threshold V1, and the release condition of the button may be set as threshold V2, in which threshold V1 and threshold V2 have different values to avoid incorrect determinations. When the user presses the button, such that the displacement detected by the sensing module is larger than the predetermined threshold V1, such a condition may be regarded as coinciding with the triggering condition of the button. The processor sends a triggering signal to the computer, indicating that the button is triggered. After that, when the user releases the button, such that the displacement detected by the sensing module is smaller than the predetermined threshold V2, such a condition may be regarded as coinciding with the release condition of the button. The processor sends a release signal to the computer indicating that the button is released.

Referring to FIG. 4B, the triggering condition of the button may be slope S1, and the release condition of the button may be slope S2, in which the slope S1 is positive and the slope S2 is negative. When the user presses the button, such that the displacement detected by the sensing module in a period of time is larger than the predetermined slope S1, such a condition may be regarded as coinciding with the triggering condition of the button. The processor sends a triggering signal to the computer indicating that the button is triggered. After that, when the user releases the button, such that the displacement detected by the sensing module in a period of time is smaller than the predetermined slope S2, such a condition may be regarded as coinciding with the release condition of the button. The processor sends a release signal to the computer indicating that the button is released.

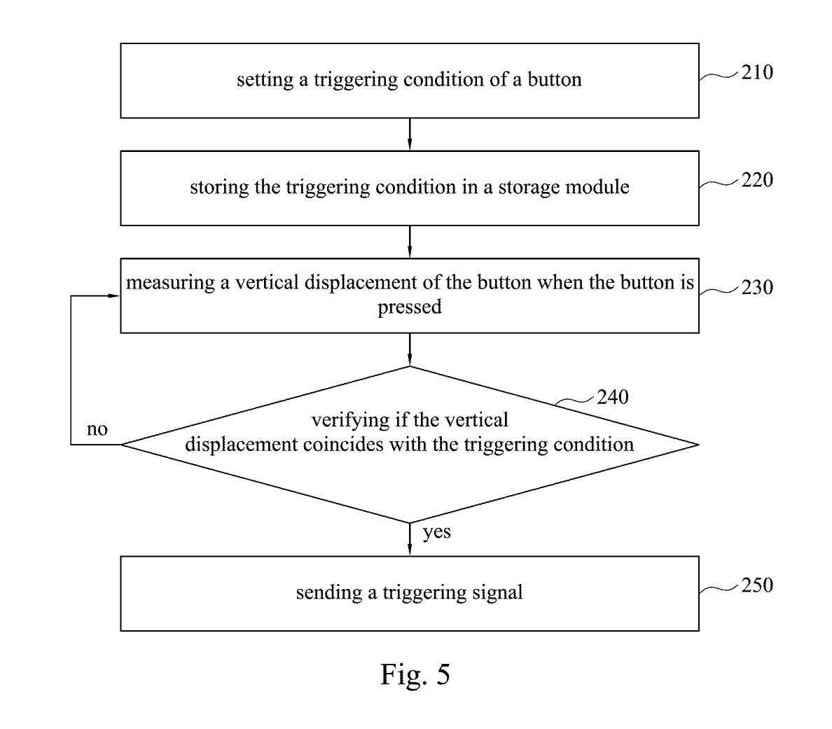

FIG. 5 is a flow chart of a customize button input method according to an embodiment of the disclosure. The customize button input method starts from step 210. The step 210 includes setting a triggering condition of a button, in which the triggering condition may be a predetermined threshold or slope, as shown in FIGS. 4A and 4B. The step 210 further includes repeatedly pressing the button to obtain an average value. The triggering condition may be a user setting, or may be a factory setting. Also, the triggering condition may be individually set, or may be set in groups.

The customize button input method proceeds to step 220. The step 220 includes storing the triggering condition in a storage module. The storage module may be integrated in the input device, or may be disposed in a computer connected with the input device.

The customize button input method proceeds to step 230. The step 230 includes measuring the displacement of the button when the button is pressed. The measuring step may be applied through a contact measurement or a contactless measurement. For example, the sensing module for measuring the displacement may be a capacitive sensing module, a magnetic sensing module, an infrared sensing module, a resistor sensing module, an ultrasonic sensing module, or a piezoelectric sensing module. The displacement may be expressed in distance, capacitance variation, resistance variation, or voltage variation.

The customize button input method proceeds to step 240. The step 240 includes verifying if the displacement coincides with a predetermined triggering condition. Once the displacement coincides with the predetermined triggering condition, the method proceeds to step 250. The step 250 includes sending a triggering signal when the displacement of the button coincides with the predetermined triggering condition. More specifically, the displacement of the button detected by the sensing module is transmitted to the processor, and the processor compares the displacement with the triggering condition stored in the storage device. Once the vertical displacement coincides with the predetermined triggering condition, the processor sends the triggering signal to the computer.

The present disclosure provides a customize input device, in which a triggering condition of each button is predetermined, such that the triggering condition of each button corresponds to a particular user's habit to thereby achieve a customize setting button. Thus, the button may be triggered immediately and inadvertent triggering may be prevented.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A customize input device, comprising:
at least one button;
at least one sensing module disposed under the button for measuring a displacement of the button;
a storage module for storing at least one triggering condition of the button; and
a processor connected to the sensing module, wherein the processor compares the displacement with the triggering condition, and sends a triggering signal when the displacement coincides with the triggering condition.

2. The device of claim 1, wherein the button is a keyboard button or a mouse button.

3. The device of claim 1, wherein the at least one button, the at least one sensing module, and the at least one triggering condition are plural, and each of the triggering conditions corresponds to one of the buttons, or corresponds to a group of the buttons.

4. The device of claim 1, wherein the sensing module is a capacitive sensing module, a magnetic sensing module, an infrared sensing module, a resistor sensing module, or an ultrasonic sensing module.

5. The device of claim 1, wherein the sensing module is a piezoelectric sensing module.

6. A customize button input method, comprising:
setting a triggering condition of a button;
storing the triggering condition in a storage module;
measuring a displacement of the button when the button is pressed; and
comparing the displacement with the triggering condition, and sending a triggering signal when the displacement coincides with the triggering condition.

7. The method of claim 6, wherein measuring the displacement of the button is applied through a contact measurement.

8. The method of claim 6, wherein measuring the displacement of the button is applied through a contactless measurement.

9. The method of claim 6, further comprising:
setting a release condition of the button;
storing the release condition in the storage module;
comparing the displacement with the release condition, and sending a release signal when the displacement coincides with the release condition.

10. The method of claim 6, wherein the triggering condition is a threshold or a slope.
